(19) United States
(12) Patent Application Publication
(10) Pub. No.: US 2004/0109366 A1
(43) Pub. Date: Jun. 10, 2004

(54) Variable-delay precharge circuits and methods

(76) Inventors: Jang-Won Moon, Kyungki-do (KR); Sung-Hoon Kim, Kyungki-do (KR); Kyoung-Ho Kim, Kyungki-do (KR); Joung-Yeal Kim, Kyungki-do (KR); Ho-Young Song, Kyungki-do (KR)

Correspondence Address: Robert M. Meeks, Myers Bigel Sibley & Sajovec, Post Office Box 37428, Raleigh, NC, 27627, US

(21) Appl. No.: 10/715,015

(22) Filed: Nov. 18, 2003

(30) Foreign Application Priority Data
Dec. 4, 2002 (KR) 2002-76704

(51) Int. Cl. G11C 7/00

(52) U.S. Cl. 365/200

(57) ABSTRACT

A memory device includes a data line and a variable delay precharge circuit that receives a column bank address signal and a write enable signal and that precharges the data line responsive to the column bank address signal at a time that is determined by a state of the write enable signal. For example, the variable delay precharge circuit may include a precharge circuit operative to precharge the data line responsive to a precharge control signal, and a variable delay precharge control signal generator circuit that receives the column bank address signal and the write enable signal and that delays the precharge control signal with respect to the column bank address signal responsive to the write enable signal. The variable delay precharge circuit may precharge the data line after a first predetermined time period following assertion of the column bank address signal when the write enable signal indicates a read operation, and may precharge the data line after a second predetermined time period following assertion of the column bank address signal when the write enable signal indicates a write operation. The second time period may be shorter than the first time period.

### RELATED APPLICATION

This application claims the priority of Korean Patent Application No. 2002-76704, filed Dec. 4, 2002 the disclosure of which is incorporated by reference herein in its entirety.

### BACKGROUND OF THE INVENTION

The present invention relates to memory devices, and more particularly, to precharge circuits for memory devices.

A semiconductor memory device typically includes a precharge circuit that precharges data input/output lines prior to a next operation after a write or read operation is completed. Such a precharge circuit typically receives a precharge control signal and precharges data input/output lines in response to the precharge control signal. The precharge circuit generally includes a PMOS transistor that has a gate for receiving a precharge control signal, and a drain and a source respectively connected to a pair of data input/output lines. Thus, if the precharge control signal is logic “low,” the precharge circuit carries out a precharge operation.

In a semiconductor memory device having a plurality of banks, such a precharge control signal may be generated according to a bank select signal. In particular, a column bank address (CBA) signal used for selecting a predetermined bank among the plurality of banks may be delayed for a predetermined period of time to generate the precharge control signal.

FIG. 1A is a circuit diagram of a precharge control signal generator circuit for controlling a precharge circuit that precharges data input/output lines according to the prior art, and FIG. 1B is a timing diagram illustrating a column bank address signal CBA and a signal output from the precharge control signal generator circuit shown in FIG. 1A. Referring to FIG. 1A, a precharge control signal generator circuit 1000 includes a delay 10, a NOR circuit 15, and an inverter 16. The delay 10 has a plurality of inverters 11, 12, 13, and 14, which are connected in series. The delay 10 delays a column bank address signal CBA for a predetermined period of time, and then outputs a signal. The NOR circuit 15 receives the column bank address signal CBA and the signal output from the delay 15, performs a NOR operation on the column bank address signal CBA and the signal output from the delay 15, and outputs the result of the NOR operation. The inverter 16 inverts a signal output from the NOR circuit 15 and outputs a precharge control signal PIOPRB.

As shown in FIG. 1B, the precharge control signal PIOPRB is synchronized with a rising edge of the column bank address signal CBA and transitioned to logic “high.” Also, at a falling edge of the column bank address signal CBA, the precharge control signal PIOPRB is delayed by the delay 10 for a predetermined period of time and transitioned to logic “low.”

In a typical synchronous semiconductor memory device, the above-described operations may be constrained by specifications such as a write recovery time. The write recovery time refers to the time required for completely writing data before a read command is input after a write command. As operational frequency increases, this limitation may tighten.

The precharge control signal PIOPRB is generated by the precharge control signal generator circuit 100 as shown in FIG. 1B regardless of whether the precharge control signal PIOPRB is generated after data is written or after data is read. A precharge control signal PIOPRB after a data read operation may be delayed for a shorter period of time than a precharge control signal PIOPRB that follows a data write operation. In other words, a precharge operation after a read operation may be performed faster than a precharge operation after a write operation.

Accordingly, in an event that a precharge control signal necessary for a precharge operation after a write operation is generated differently from a precharge control signal necessary for a precharge operation after a read operation in order to adjust a precharging time, even when an operational frequency is high, limitations due to a write recovery time can be eased.

### SUMMARY OF THE INVENTION

According to some embodiments of the present invention, a memory device includes a data line and a variable delay precharge circuit that receives a column bank address signal and a write enable signal and that precharges the data line responsive to the column bank address signal at a time that is determined by a state of the write enable signal. For example, the variable delay precharge circuit may comprise a precharge circuit operative to precharge the data line responsive to a precharge control signal, and a variable delay precharge control signal generator circuit that receives the column bank address signal and the write enable signal and that delays the precharge control signal with respect to the column bank address signal responsive to the write enable signal. The variable delay precharge circuit may precharge the data line after a first predetermined time period following assertion of the column bank address signal when the write enable signal indicates a read operation, and may precharge the data line after a second predetermined time period following assertion of the column bank address signal when the write enable signal indicates a write operation. The second time period may be shorter than the first time period.

In further embodiments, the variable delay precharge control signal generator circuit may include a precharge control signal generator circuit that receives the column bank address signal, that generates first and second delayed signals from the column address bank signal that are delayed by respective different first and second time periods with respect to the column address bank signal, and that applies to the precharge circuit, responsive to a precharge delay control signal, a selected one of a first precharge control signal generated from the first delayed signal and a second precharge signal generated from the second delayed signal. The variable delay precharge control signal generator circuit includes a precharge delay control circuit that generates the precharge delay control signal responsive to the write enable signal.

According to further aspects of the present invention, a memory device includes a pair of data input/output lines. A precharge circuit precharges the pair of data input/output lines responsive to a precharge control signal. A precharge control signal generator circuit receives a column bank address signal, generates first and second delayed signals from the column address bank signal that are delayed by respective different first and second time periods with respect to the column address bank signal, and applies to the precharge circuit, responsive to a precharge delay control signal, a selected one of a first precharge control signal generated from the first delayed signal and a second precharge signal generated from the second delayed signal. A precharge delay control circuit generates the precharge delay control signal responsive to a write enable signal.

In further embodiments of the present invention, a precharge control circuit for controlling a precharge circuit of a semiconductor memory device includes a precharge control signal generator circuit that receives a column bank address signal, that generates first and second delayed signals from the column address bank signal that are delayed by respective different first and second time periods, and that applies, responsive to a precharge delay control signal, a selected one of a first precharge control signal generated from the first delayed signal and a second precharge signal generated from the second delayed signal. The precharge control circuit further includes a precharge delay control circuit that generates the precharge delay control signal responsive to a write enable signal. The precharge delay control circuit causes application of the first precharge control signal after a read operation of the memory device and application of the second precharge control signal after a write operation of the memory device. The first period of time may be longer than the second period of time.

Related methods of operating memory devices are also described.

### BRIEF DESCRIPTION OF THE DRAWINGS

FIG. 1A is a circuit diagram of a conventional precharge control signal generator circuit.

FIG. 1B is a timing diagram illustrating a column bank address signal and a precharge control signal for the circuit of FIG. 1A.

FIG. 2 is a circuit diagram of a precharge control circuit according to some embodiments of the present invention.

FIG. 3 is a timing diagram illustrating exemplary operations for precharging data input/output lines after a read operation in a memory device according to some embodiments of the present invention.

FIG. 4 is a timing diagram illustrating exemplary operations for precharging after a write operation in a memory device according to further embodiments of the present invention.

FIGS. 5A and 5B are views illustrating simulation of exemplary precharge operations according to some embodiments of the present invention.

FIG. 6 is a flowchart illustrating exemplary operations for generating a precharge control signal according to additional embodiments of the present invention.

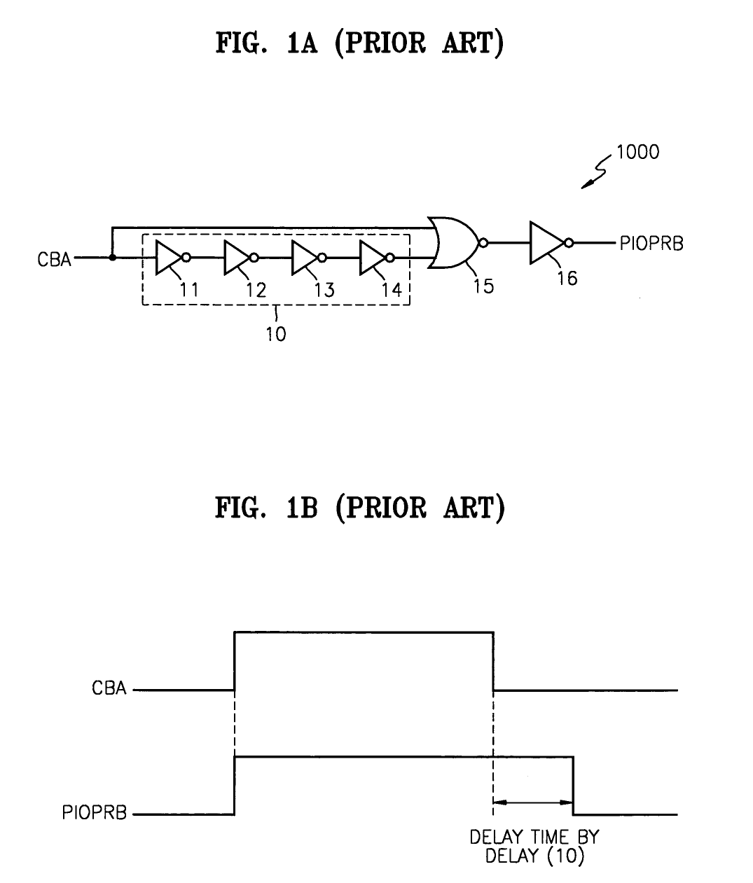

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. It will be understood that when elements are referred to as being coupled to one another, this coupling may be direct or via one or more intervening elements.

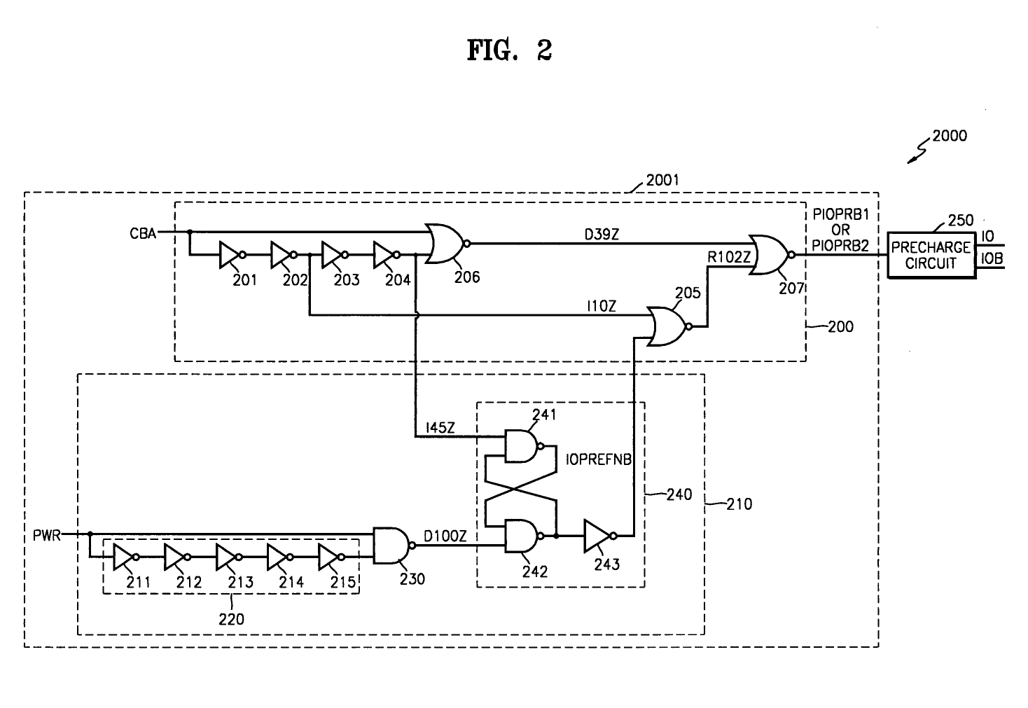

FIG. 2 is a circuit diagram of a variable delay precharge circuit according to some embodiments of the present invention. Referring to FIG. 2, the variable delay precharge circuit 2000 includes a precharge circuit 250 and a precharge control circuit 2001. The precharge control circuit 2000 includes a precharge control signal generator circuit 200 and a precharge delay control circuit 210. The precharge control signal generator circuit 200 receives a column bank address signal CBA and generates a first precharge control signal PIOPRB1 or a second precharge control signal PIOPRB2 from the column bank address signal CBA. The precharge control signal generator circuit 200 includes a plurality of inverters 201, 202, 203, and 204 and a plurality of NOR circuits 205, 206, and 207.

The precharge delay control circuit 210 controls the precharge control signal generator circuit 200 in response to a write enable signal PWR so that that the precharge control signal generator circuit 200 applies a selected one of the first precharge control signal PIOPRB1 or the second precharge control signal PIOPRB2 to the precharge circuit 250. The precharge delay control circuit 210 includes a delay 220, a NOR circuit 230, and a latching/inverting circuit 240.

An input node of the inverter 201 receives the column bank address signal CBA. An output node of the inverter 201 is connected to an input node of the inverter 202. An output node of the inverter 202 is connected to an input node of the inverter 203 and an output node of the inverter 203 is connected to an input node of the inverter 204. The NOR circuit 206 receives the column bank address signal CBA and a signal output from the inverter 204, performs a NOR combination of the column bank address signal CBA and the signal output from the inverter 204, and responsively produces a signal D39Z. The NOR circuit 205 receives a signal I10Z output from the inverter 202 and a signal IOPREFNB output from the latching/inverting circuit 240, performs a NOR combination of the signal I10Z and the signal IOPREFNB, and responsively outputs a signal R102Z.

The NOR circuit 207 receives the signal D39Z output from the NOR circuit 206 and the signal R10Z output from the NOR circuit 205, performs a NOR operation on the signal D39Z and the signal R10Z, and responsively outputs the first precharge control signal PIOPRB1 or the second precharge control signal PIOPRB2. The first precharge control signal PIOPRB1 or the second precharge control signal PIOPRB2 is applied to a precharge circuit 250 and controls precharging of a pair of data input/output lines IO and IOB. The pair of data input/output lines IO and IOB may be a pair of global input/output lines of a semiconductor memory device.

The delay 220 includes a plurality of inverters 211, 212, 213, 214, and 215, which are connected in series. It is preferable that delay 220 includes an odd number of inverters. The delay 210 receives the write enable signal PWR, delays the write enable signal PWR for a predetermined period of time, and outputs an inverted signal. The NOR circuit 230 receives the write enable signal PWR and the inverted signal output from the delay 220, performs a NOR operation on the write enable signal PWR and the inverted signal output from the delay 220, and responsively outputs a signal D100Z.

The latching/inverting circuit 240 includes NOR circuits 241 and 242, which are coupled in a latch configuration. An inverter 243 is connected to an output node of the NOR circuit 242. The NOR circuit 241 receives a signal I45Z output from the inverter 204 and a signal output from the NOR circuit 242, performs a NOR operation on the signal I45Z and the signal output from the NOR circuit 242, and responsively outputs a signal. The NOR circuit 242 receives the signal D100Z output from the NOR circuit 230 and the signal output from the NOR circuit 241, performs a NOR operation on the signal D100Z and the signal output from the NOR circuit 241, and responsively outputs a signal. The latching/inverting circuit 240 receives, latches, and inverts the signal I45Z output from the inverter 204 and the signal D100Z output from the NOR circuit 230, and outputs a signal IOPREFNB. While the semiconductor memory device is performing a write operation, the write enable signal PWR shown in FIG. 2 takes on a first logic state, e.g., logic “high.” After the semiconductor memory device finishes the write operation, the write enable signal PWR takes on a second logic state, e.g., logic “low.”

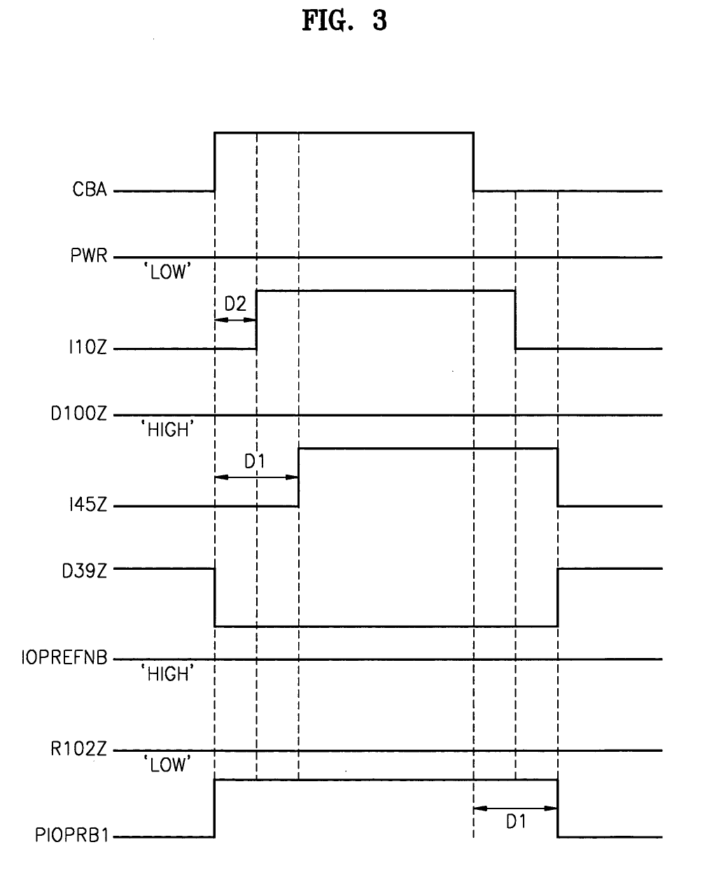

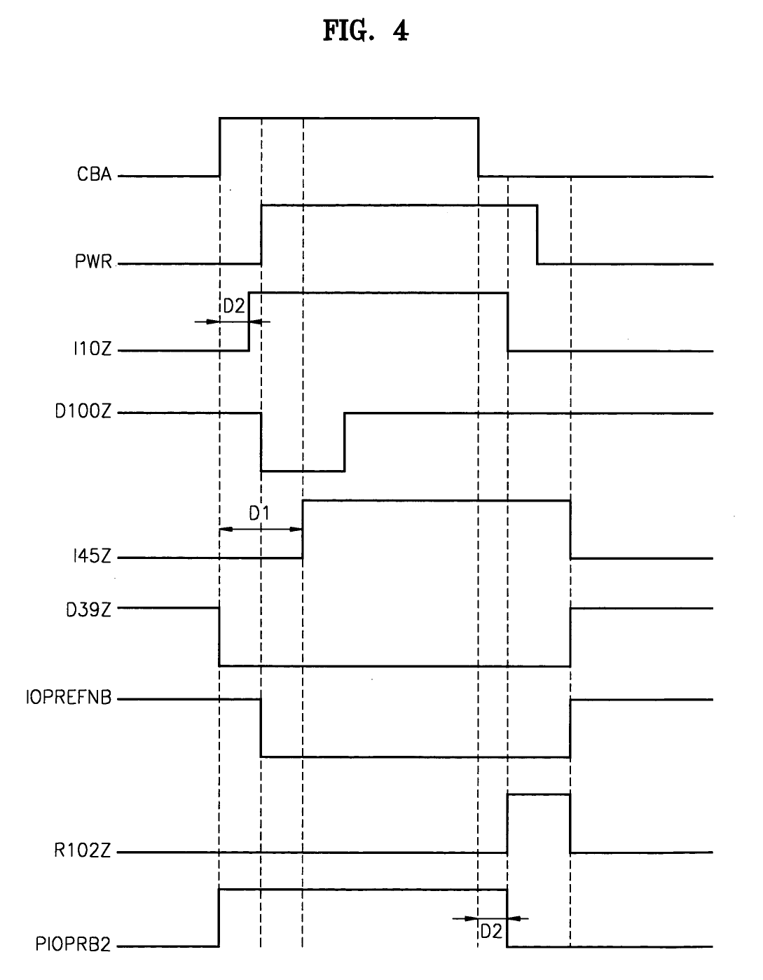

FIG. 3 is a timing diagram illustrating a case where data input/output lines are precharged after a read operation of a semiconductor memory device in a precharge control circuit according to some embodiments of the present invention, and FIG. 4 is a timing diagram illustrating a case where data input/output lines are precharged after a write operation of a semiconductor memory device in a precharge control circuit according to further embodiments of the present invention. The operation of the precharge control circuit 2000 when data input/output lines are precharged after data is read will now be described. When data is read, as shown in FIG. 3, the write enable signal PWR is kept at logic “low.” Thus, the signal output from the NOR circuit 230 is logic “high.” If the column bank address signal CBA is activated, the inverter 204 outputs the signal I45Z that is generated by delaying the column bank address signal CBA for a first period of time d1. The first period of time d1 is generated by delays of the inverters 201, 202, 203, and 204. The latching/inverting circuit 240 performs an OR operation on the signal output from the inverter 204 and the signal D100Z output from the NOR circuit 230 and responsively outputs the signal IOPREFNB at a logic “high.” Thus, the NOR circuit 205 outputs the signal R102Z that is logic “low,” regardless of the signal I10Z output from the inverter 202. In this situation, the NOR circuit 207 serves as an inverter and outputs the first precharge control signal PIOPRB1. The first precharge control signal PIOPRB1 is delayed for the first period of time d1 at the falling edge of the column bank address signal CBA, and then becomes logic “low.”

The operation of the precharge control circuit 2000 when the data input/output lines are precharged after data is written will now be described. When data is written, the write enable signal PWR goes to logic “high.” As shown in FIG. 4, the NOR circuit 230 receives the write enable signal PWR and the signal output from the delay 220 and generates an inverted pulse having a predetermined pulse width. The signal I10Z output from the inverter 202, the signal I45Z output from the inverter 204, and the signal D39Z output from the NOR circuit 206 are as shown in FIG. 3. When the write enable signal PWR is “high,” the signal D100Z output from the NOR circuit 230 is an inverted pulse in response to the write enable signal PWR. Thus, the signal IOPREFNB output from the latching/inverting circuit 240 is transitioned to logic “low” as shown in FIG. 4.

The logic state of the NOR circuit 205 is transitioned in response to the signal IOPREFNB output from the latching/inverting circuit 240, the signal output R102Z from the NOR circuit 205 is transitioned as shown in FIG. 4, and the NOR circuit 207 generates the second precharge control signal PIOPRB2 in response to the signal D39Z output from the NOR circuit 206 and the signal R102Z output from the NOR circuit 205. The second precharge control signal PIOPRB2 is delayed for a second period of time d2 at the falling edge of the column bank address signal CBA, and then becomes logic “low.” The second period of time d2 is generated by delay times of the inverters 201 and 202 and is shorter than the first period of time d1 generated by delay times of the inverters 201, 202, 203, and 204.

In other words, according to the present invention, the precharge control signal generator circuit 200 selectively outputs the first precharge control signal PIOPRB1 or the second precharge control signal PIOPRB2 in response to the write enable signal PWR. Also, the first and second precharge control signals PIOPRB1 and PIOPRB2 can be generated so that an instant of time when the first precharge control signal PIOPRB1 is activated can be earlier than an instant of time when the second precharge control signal PIOPRB2 is activated. Thus, the time required for performing a precharging operation after a write operation can be shortened.

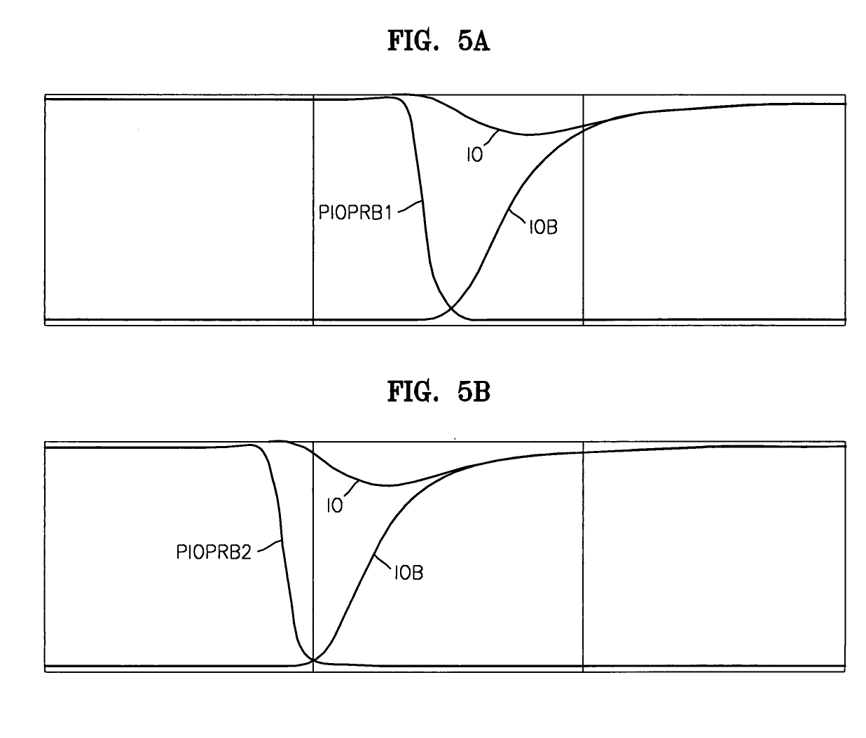

FIG. 5A is a simulated waveform diagram illustrating the first precharge signal PIOPRB1 for performing a precharge operation after a read operation of the semiconductor memory device and voltage levels of the data input/output lines IO and IOB that are precharged in response to the first precharge control signal PIOPRB1. FIG. 5B is a simulated waveform diagram illustrating the second precharge signal PIOPRB2 for performing a precharge operation after a write operation of the semiconductor memory device and voltage levels of the data input/output lines IO and IOB that are precharged in response to the second precharge control signal PIOPRB2. In FIGS. 5A and 5B, the first and second precharge control signals PIOPRB1 and PIOPRB2 are transitioned from logic “high” to logic “low,” and two signals of the data input/output liens IO and IOB are transitioned to logic “low” and converge at a predetermined voltage level. Comparing FIG. 5A with FIG. 5B, the first precharge control signal PIOPRB1 shown in FIG. 5A is activated slower than the second precharge control signal PIOPRB2 shown in FIG. 5B. Thus, the precharge operation presented in FIG. 5A starts earlier than the precharge operation presented in FIG. 5B. As described previously, when a precharge operation is performed after a write operation, a precharge control signal is activated earlier than when a precharge operation is performed after a read operation, the precharging time required for carrying out the precharging operation after a write operation can be shortened.

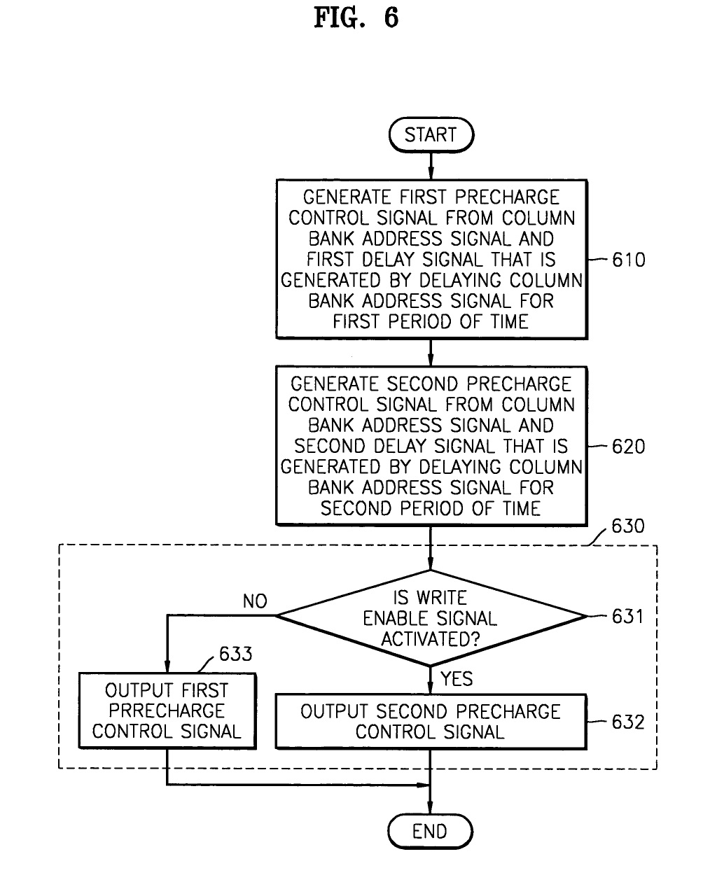

FIG. 6 is a flowchart for explaining a method of generating a precharging control signal according to an embodiment of the present invention. Referring to FIG. 6, in step 610, a first precharge control signal is generated. In step 620, a second precharge control signal is generated. In step 630, the first precharge control signal or the second precharge control signal is selectively output in response to a write enable signal.

The method of generating the precharge control signal according to an embodiment of the present invention will be described in more detail with reference to FIGS. 2 and 6. The first precharge control signal PIOPRB1 is generated from the column bank address signal CBA and the first signal I45Z that is generated by delaying the column bank address signal CBA for the first period of time d1. The second precharge control signal PIOPRB2 is generated from the column bank address signal CBA and the second signal I10Z that is generated by delaying the column bank address signal for the second period of time d2. The first and second precharge control signals PIOPRB1 and PIOPRB2 are generated by the precharge control signal generator circuit 200. Step 630 includes steps 631, 632, and 633. In step 631, it is determined whether the write enable signal PWR is activated. If the write enable signal PWR is activated, in step 632, the second precharge control signal PIOPRB2 is output. If the write enable signal PWR is not activated, in step 633, the first precharged control signal PIOPRB1 is output. Step 630 is performed by the precharge delay control circuit 210 of the precharge control circuit 2000 shown in FIG. 2. The precharge control signal generator circuit 200 selectively outputs the first precharge control signal PIOPRB1 or the second precharge control signal PIOPRB2 in response to the operation of the precharge delay control circuit 210.

As described above, according to some embodiments of the present invention, a precharge control signal for a precharging after a write operation can be generated differently than a precharge control signal for precharging after a read operation. Thus, the precharge operation after the write operation can start earlier than the precharge operation after the read operation. As a result, the precharging time required for performing the precharging operation after the write operation can be shortened. Therefore, even when operational frequency is high, a sufficient period of write recovery time can be secured.

In the drawings and specification, there have been disclosed typical embodiments of the invention and, although specific terms are employed, they are used in a generic and descriptive sense only and not for purposes of limitation, the scope of the invention being set forth in the following claims. Although the invention has been described with reference to particular embodiments, it will be apparent to one of ordinary skill in the art that modifications of the described embodiments may be made without departing from the spirit and scope of the invention

What is claimed is:

1. A memory device, comprising:
a data line; and
a variable delay precharge circuit that receives a column bank address signal and a write enable signal and that precharges the data line responsive to the column bank address signal at a time that is determined by a state of the write enable signal.

2. The memory device of claim 1, wherein the variable delay precharge circuit comprises:
a precharge circuit operative to precharge the data line responsive to a precharge control signal;
a variable delay precharge control signal generator circuit that receives the column bank address signal and the write enable signal and that delays the precharge control signal with respect to the column bank address signal responsive to the write enable signal.

3. The memory device of claim 2, wherein the variable delay precharge control signal generator circuit comprises:
a precharge control signal generator circuit that receives the column bank address signal, that generates first and second delayed signals from the column address bank signal that are delayed by respective different first and second time periods with respect to the column address bank signal, and that applies to the precharge circuit, responsive to a precharge delay control signal, a selected one of a first precharge control signal generated from the first delayed signal and a second precharge signal generated from the second delayed signal; and
a precharge delay control circuit that generates the precharge delay control signal responsive to the write enable signal.

4. The memory device of claim 1, wherein the variable delay precharge circuit precharges the data line after a first predetermined time period following assertion of the column bank address signal when the write enable signal indicates a read operation, and wherein the variable delay precharge circuit precharges the data line after a second predetermined time period following assertion of the column bank address signal when the write enable signal indicates a write operation.

5. The memory device of claim 4, wherein the second time period is shorter than the first time period.

6. A memory device comprising:
a pair of data input/output lines;
a precharge circuit that precharges the pair of data input/output lines responsive to a precharge control signal;
a precharge control signal generator circuit that receives a column bank address signal, that generates first and second delayed signals from the column address bank signal that are delayed by respective different first and second time periods with respect to the column address bank signal, and that applies to the precharge circuit, responsive to a precharge delay control signal, a selected one of a first precharge control signal generated from the first delayed signal and a second precharge signal generated from the second delayed signal; and
a precharge delay control circuit that generates the precharge delay control signal responsive to a write enable signal.

7. The memory device of claim 6, wherein the first precharge control signal rises in synchronization with a rising edge of the column bank address signal and falls the first period of time after an immediately succeeding falling edge of the column bank address signal, and wherein the second precharge control signal rises in synchronization with a rising edge of the column bank address signal and falls the second period of time after an immediately succeeding falling edge of the column bank address signal.

8. The memory device of claim 6, wherein the pair of data input/output lines are a pair of global input/output lines of the memory device.

9. A precharge control circuit for controlling a precharge circuit of a semiconductor memory device, the precharge control circuit comprising:
a precharge control signal generator circuit that receives a column bank address signal, that generates first and second delayed signals from the column address bank signal that are delayed by respective different first and second time periods, and that applies, responsive to a precharge delay control signal, a selected one of a first precharge control signal generated from the first delayed signal and a second precharge signal generated from the second delayed signal; and
a precharge delay control circuit that generates the precharge delay control signal responsive to a write enable signal,
wherein the precharge delay control circuit causes application of the first precharge control signal after a read operation of the memory device and application the second precharge control signal after a write operation of the memory device.

10. The precharge control circuit of claim 9, wherein the first period of time is longer than the second period of time.

11. The precharge control circuit of claim 9, wherein the control circuit comprises:
a first delay that receives the write enable signal and outputs an inverted delayed signal therefrom;
a NOR circuit that receives the write enable signal and the inverted delayed signal output from the first delay, performs a NOR operation on the write enable signal and the inverted signal, and responsively outputs a signal; and
a latching/inverting circuit that receives, latches, and inverts the signal output from the NOR circuit and the first delay signal, and responsively outputs a signal.

12. The precharge control circuit of claim 11, wherein the first delay comprises an odd number of inverters connected in series.

13. The precharge control circuit of claim 9, wherein the precharge control signal generator circuit comprises:
a first NOR circuit that receives the second delay signal and the signal output from the latching/inverting circuit, performs a NOR operation on the second delay signal and the signal output from the latching/inverting circuit, and responsively outputs a first signal;
a second NOR circuit that receives the column bank address signal and the first delay signal, performs a NOR operation for the column bank address signal and the first delay signal, and responsively outputs a second signal; and
a third NOR circuit that receives the first and second signals output from the first and second NOR circuits, performs a NOR operation on the first and second signals, and responsively outputs a third signal.

14. The precharge control circuit of claim 13, wherein, if the write enable signal indicates a write operation, the precharge control signal generator circuit generates the first precharge control signal, and wherein, if the write enable signal indicates a read operation, the precharge control signal generator circuit generates the second precharge signal.

15. A method of generating a precharge control signal for a precharge circuit of a memory device, the method comprising:
receiving a column bank address signal;
generating first and second delayed signals from the column bank address signal that are delayed respective first and second time periods;
logically OR'ing the column bank address signal and the first delayed signal to generate a first signal;
logically OR'ing the column bank address signal and the second delayed signal to generate a second signal;
generating one of a first precharge control signal responsive to the first signal and a first state of a write enable signal; and
generating a second precharge control signal responsive to the second signal and a second state of the write enable signal,
wherein the first time period is greater than the second time period.

16. The method of claim 15, wherein the first precharge control signal is generated responsive to a read operation of the memory device, and wherein the second precharge control signal is generated responsive to a write operation of the memory device.
